(19) United States
(12) Patent Application Publication
(10) Pub. No.: US 2007/0128819 A1
(43) Pub. Date: Jun. 7, 2007

(54) FILM FORMING METHOD AND METHOD OF MANUFACTURING SEMICONDUCTOR DEVICE

(76) Inventor: Yuki Miyanami, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/470,036

(22) Filed: Sep. 5, 2006

(30) Foreign Application Priority Data
Dec. 2, 2005 (JP) P2005-348639

(51) Int. Cl. H01L 21/331

(52) U.S. Cl. 438/357

(57) ABSTRACT

A film forming method for forming an arsenic-doped silicon layer (epitaxially grown silicon layer) by epitaxial growth includes the step of supplying a gas containing arsenic as a dopant into the atmosphere for the epitaxial growth while keeping the epitaxial growth atmosphere at the atmospheric pressure.

### CROSS REFERENCES TO RELATED APPLICATIONS

The embodiment of the present invention contains subject matter related to Japanese Patent Application JP 2005-348639 filed with the Japanese Patent Office on Dec. 2, 2005, the entire contents of which being incorporated herein by reference.

### BACKGROUND OF THE INVENTION

1. Field of the Invention

The present invention relates to a film forming method and a method of manufacturing a semiconductor device which can be applied to the technology of forming an elevated source drain of a CMOS device.

2. Description of the Related Art

Enhancement of the degree of integration and the operating speed of transistors have been realized by miniaturization of transistors, based on the scaling rule. In recent years, however, the short channel effect attendant on the miniaturization has produced adverse influences on device characteristics, such as degradation of roll-off characteristic. Suppression of the short channel effects may need a reduction of the diffusion depth (Xj) of an impurity, but an increase in parasitic resistance has come to be a problem in a MOSFET structure according to the related art. The elevated source drain structure is investigated as a structure probably necessary for suppression of the short channel effect, since it is possible with the structure to make the diffusion depth (Xj) small and to restrain the increase in the parasitic resistance.

In order to suppress the diffusion depth (Xj) in forming the elevated source drain structure, a technology in which selective epitaxial growth of silicon is conducted by introducing a dopant into the growth atmosphere is investigated, as a substitute for a process of conducting the steps of formation of a selectively epitaxially grown silicon layer, ion implantation, and rapid thermal annealing (RTA) according to the related art (refer to, for example, Gael Borot, Laurent Rubaldo, Nicolas Breil, Alexandre Talbot and Didier Dutartre, “Segregation and Growth Behavior of As-Doped Epi and Poly Si”, Fourth International Conference on Silicon Epitaxy and Heterostructures (ICSI-4), 25, pp. 2 to 22 and pp. 274 to 275, 2005). For instance, a process of doping with arsenic (As) has been investigated for use in the case of NMOS transistors. In the vacuum epitaxial growth according to the related art, however, a lowering in the growth rate attendant on an increase in the arsenic (As) concentration has been a problem. Besides, in the vacuum epitaxial growth, it has been difficult to form an epitaxially grown silicon layer doped with arsenic in a high concentration, for example, 10¹⁹/cm³.

### SUMMARY OF THE INVENTION

Thus, there has been the problem in the related art in that it is very difficult to grow silicon doped with arsenic in a high concentration, for example, a concentration of not less than about 10¹⁹/cm³ by epitaxial growth, without lowering the growth rate.

Therefore, there is need for a method of forming an epitaxially grown silicon layer doped with arsenic in a high concentration, without lowering the growth rate, by conducting the epitaxial growth at the atmospheric pressure.

According to an embodiment of the present invention, there is provided a film forming method for forming an arsenic-doped silicon layer by epitaxial growth, including the step of supplying a gas containing arsenic as a dopant into the atmosphere for the epitaxial growth while keeping the epitaxial growth atmosphere at the atmospheric pressure.

In this film forming method, the gas containing arsenic as a dopant is supplied into the atmosphere for the epitaxial growth while keeping the epitaxial growth atmosphere at the atmospheric pressure, whereby an epitaxially grown silicon layer doped with arsenic in a high concentration, for example, a concentration of not less than about 1×10¹⁹/cm³ can be formed, without lowering the growth rate. Specifically, the epitaxially grown silicon layer doped with arsenic in the high concentration can advantageously be formed at a higher growth rate than that in the epitaxial growth of a silicon layer doped with arsenic in a low concentration under a reduced pressure (vacuum) according to the related art. As a result, an epitaxially grown silicon layer doped with arsenic in a high concentration can be formed at a high rate.

According to another embodiment of the present invention, there is provided a method of manufacturing a semiconductor device, including the step of forming an arsenic-doped silicon layer on source/drain regions formed in a silicon substrate by selective epitaxial growth, wherein the step of forming the arsenic-doped silicon layer includes the step of supplying a gas containing arsenic as a dopant into the atmosphere for the selective epitaxial growth while keeping the selective epitaxial growth atmosphere at the atmospheric pressure.

In this manufacturing method, the gas containing arsenic as a dopant is supplied into the atmosphere for the epitaxial growth while keeping the epitaxial growth atmosphere at the atmospheric pressure, whereby an epitaxially grown silicon layer doped with arsenic in a high concentration, for example, a concentration of not less than about 1×10¹⁹/cm³ can be formed, without lowering the growth rate. Therefore, the silicon layer doped with arsenic in the high concentration can be formed selectively on the source/drain regions. Therefore, there is obtained the merit that the so-called elevated source drain structure can be easily formed. As a result, the diffusion depth (Xj) of the source/drain regions can be kept small, and the increase in parasitic resistance can be restrained. Accordingly, a high-performance transistor with the short channel effect suppressed can be manufactured advantageously.

### BRIEF DESCRIPTION OF THE DRAWINGS

FIG. 1 is a schematic configuration diagram of an example of an epitaxial growth apparatus for carrying out an embodiment of the film forming method in the present invention;

FIG. 2 is a diagram showing the relationship between growth rate and arsine flow rate, with the growth temperature as a parameter;

FIG. 3 is a diagram showing the relationship between growth rate and arsine flow rate, with the flow rate of dicyclosilane as a parameter;

FIG. 4 is a diagram showing the relationship between growth rate and arsine flow rate, in the case where the growth rate is 700° C.;

FIG. 5 is a diagram showing the relationship between growth rate and arsine flow rate, with the flow rate of hydrogen chloride as a parameter;

FIG. 6 is a diagram showing the relationship between growth rate and arsine flow rate;

FIG. 7 is a diagram showing the relationship between the concentration of arsenic (As) in an epitaxially grown silicon layer and the flow rate of arsine (AsH₃), in the epitaxial growth conducted by the film forming method in the present invention; and

FIGS. 8A and 8B are manufacturing step sectional diagrams showing a first embodiment of the method of manufacturing a semiconductor device in the present invention.

### DETAILED DESCRIPTION OF THE PREFERRED EMBODIMENTS

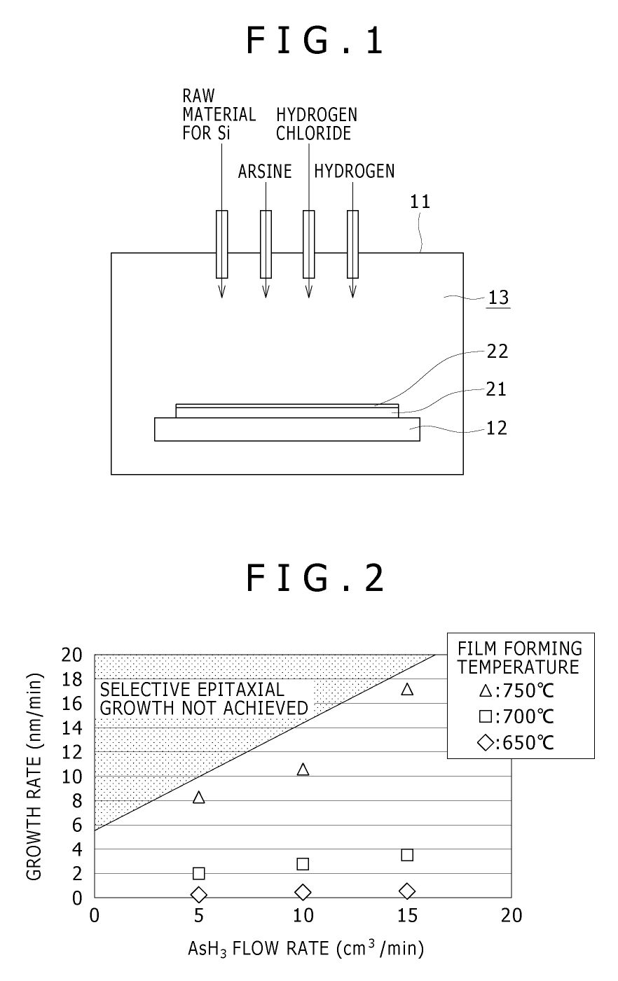

Now, an embodiment of the film forming method in the embodiment of the present invention will be described below, referring to FIG. 1. FIG. 1 is a schematic configuration diagram showing an example of an epitaxial growth apparatus for carrying out the embodiment of the film forming method in the present invention.

As shown in FIG. 1, a substrate 21 on which to form a film is mounted on a stage 12 provided in a chamber 11. Into an epitaxial growth atmosphere 13 inside the chamber 11, dichlorosilane (SiH₂Cl₂), for example, is supplied as a raw material gas for silicon, and arsine (AsH₃), for example, is supplied as a gas for doping with arsenic. In this case, the pressure of the epitaxial growth atmosphere 13 (the pressure inside the chamber 11) is set at the atmospheric pressure.

Specifically, in the case where the inside volume of the chamber 11 is 5 to 20 L, for example, the pressure of the epitaxial growth atmosphere 13 is set at the atmospheric pressure (the atmospheric pressure herein is the normal atmospheric pressure on the earth, for example, 1 atm=1013 hPa); the growth temperature (e.g., the substrate temperature) is 650 to 750° C.; and, for example, dichlorosilane (SiH₂Cl₂) is used as the raw material gas for silicon, arsine (AsH₃) (diluted with hydrogen (H₂) to 1 vol. %, for example) is used as the raw material gas for the dopant (arsenic), hydrogen chloride (HCl) is used as a gas for causing selective growth, and hydrogen (H₂) is used as a gas for uniformly distributing the dopant. As for the flow rates of these gases, dichlorosilane (SiH₂Cl₂) is supplied at a flow rate of 50 to 500 cm³/min, arsine (AsH₃) (diluted with hydrogen (H₂) to 1 vol. %) at 5 to 200 cm³/min, hydrogen chloride (HCl) at 15 to 200 cm³/min, and hydrogen (H₂) at 10 to 30 L/min. With the epitaxial growth effected under these conditions, an epitaxially grown silicon layer 22 doped with arsenic in a high concentration is formed on the surface of the substrate 21.

In addition, as an apparatus with the inside volume of the chamber 11 being 5 to 20 L, for example, there is a 200 mm wafer sheet-fed type epitaxial growth apparatus. Besides, as for the method of introducing the above-mentioned gases into the inside of the chamber 11, the gases may be mixed inside the chamber 11, or they may be mixed before introduced into the chamber 11. It suffices that a uniformly mixed state of the gases is realized on the substrate 21.

Now, the results of investigations of the above-mentioned conditions for epitaxial growth will be described below.

In regard of the above-mentioned growth temperature (e.g., the substrate temperature), FIG. 2 shows the relationship between growth rate and arsine flow rate, with the growth temperature as a parameter. As shown in FIG. 2, the epitaxial growth rate is substantially zero when the growth temperature is lower than 650° C., and the selective epitaxial growth is not achieved when the growth temperature is higher than 750° C. Therefore, the growth temperature (e.g., the substrate temperature) is set in the range of 650 to 750° C., as mentioned above.

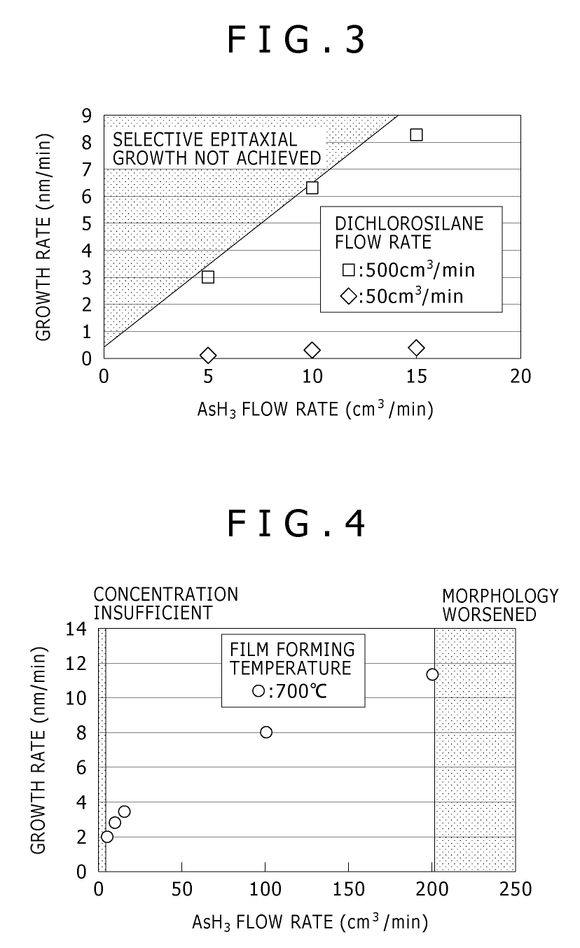

In connection with the above-mentioned gas conditions, FIG. 3 shows the relationship between growth rate and arsine flow rate, with the flow rate of dichlorosilane (SiH₂Cl₂) as a parameter. As shown in FIG. 3, the epitaxial growth rate is substantially zero when the flow rate of dichlorosilane (SiH₂Cl₂) is less than 50 cm³/min, and the selective epitaxial growth is not achieved when the flow rate of dichlorosilane (SiH₂Cl₂) is in excess of 500 cm³/min. In view of this, the flow rate of dichlorosilane (SiH₂Cl₂) is set in the range of 50 to 500 cm³/min.

FIG. 4 shows the relationship between growth rate and arsine flow rate in the case where the growth temperature is set at 700° C. As shown in FIG. 4, when the flow rate of arsine (AsH₃) (diluted with hydrogen (H₂) to 1 vol. %) is less than 5 cm³/min, the concentration of arsine is insufficient, and the growth rate is below 2 nm/min. On the other hand, when the flow rate of arsine (AsH₃) (diluted with hydrogen (H₂) to 1 vol. %) is in excess of 200 cm³/min, the morphology of epitaxial growth is worsened, though a sufficient growth rate can be secured. Therefore, the flow rate of arsine (AsH₃) (diluted with hydrogen (H₂) to 1 vol. %) is set in the range of 5 to 200 cm³/min.

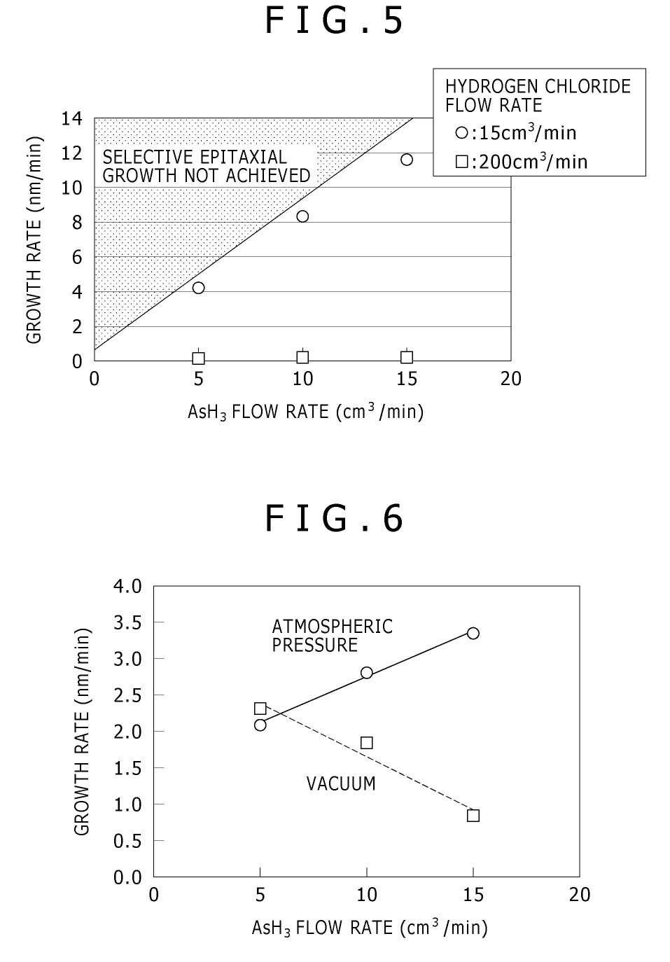

FIG. 5 shows the relationship between growth rate and arsine flow rate, with the flow rate of hydrogen chloride (HCl) as a parameter. As shown in FIG. 5, when the flow rate of hydrogen chloride (HCl) is below 15 cm³/min, the selective epitaxial growth is not achieved, whereas when the flow rate of hydrogen chloride (HCl) is higher than 200 cm³/min, epitaxial growth is not achieved but, instead, etching occurs. In view of this, the flow rate of hydrogen chloride (HCl) is set in the range of 15 to 200 cm³/min.

In addition, when the flow rate of hydrogen (H₂) is less than 10 L/min, uniformity of the distribution of arsenic is worsened. When the flow rate of hydrogen (H₂) exceeds 30 L/min, also, the uniformity of arsenic distribution is worsened. Therefore, the flow rate of hydrogen (H₂) is set in the range of 10 to 30 L/min.

In the above embodiment, as the raw material gas for silicon, other gases than dichlorosilane may be used, for example, monosilane (SiH₄), disilane (Si₂H₆), trisilane (Si₃H₈), trichlorosilane (SiHCl₃), etc.

In addition, where the inside volume of the chamber is greater than 5 to 20 L, for example, it suffices to increase the flow rates of the gases according to the proportion of the increase in the inside volume. In other words, the flow rates of the gases introduced into the chamber 11 may be regulated according to the increase in the inside volume of the chamber 11 in such a manner that the volumetric ratio among the gas flow rates calculated from the gas flow rates will be constant and, hence, the mixing ratio of the gases in the chamber will be kept constant, whereby the desired film can be formed regardlessly of the difference in the inside volume of the chamber. Accordingly, the film forming method in the embodiment of the present invention can be realized with, for example, batch-type epitaxial CVD apparatuses and sheet-fed type epitaxial CVD apparatuses for various wafer sizes.

In the next place, the tendency of epitaxial growth conducted by the film forming method in the embodiment of the present invention and the tendency of epitaxial growth at a reduced pressure (in vacuum) according to the related art were examined. The results of the examination will be described in comparison, using FIG. 6 which shows the relationship between growth rate and arsine flow rate. Incidentally, the epitaxial growth was conducted using a 200 mm wafer sheet-fed type epitaxial CVD apparatus under the conditions of a growth temperature of 700° C., a dichlorosilane (SiH₂Cl₂) flow rate of 50 cm³/min, a hydrogen chloride (HCl) flow rate of 110 cm³/min, and a hydrogen (H₂) flow rate of 20 L/min, with the arsine (AsH₃) flow rate being varied.

As shown in FIG. 6, according to the epitaxial growth at the atmospheric pressure as proposed in the embodiment of the present invention, the growth rate increases with an increase in the arsine (AsH₃) flow rate. On the other hand, in the epitaxial growth in vacuum (at a reduced pressure), the growth rate decreases with an increase in the arsine (AsH₃) flow rate. Therefore, in the case of forming an epitaxially grown silicon layer doped with arsenic in a high concentration, the growth rate in the epitaxial growth at the atmospheric pressure is higher than that in the epitaxial growth in vacuum (at a reduced pressure); as a result, the productivity of the film forming process can be enhanced.

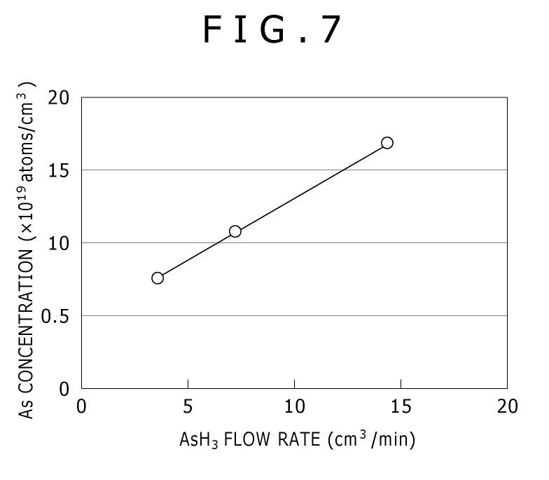

In the next place, the relationship between the concentration of arsenic (As) in the epitaxially grown silicon layer and the flow rate of arsine (AsH₃) in the case where epitaxial growth is conducted by the film forming method according to the embodiment of the present invention was examined. The examination results will be described below, using FIG. 7 which shows the relationship between As concentration and AsH₃ flow rate.

It is seen from FIG. 7 that the concentration of arsenic (As) in the epitaxially grown silicon layer increases with an increase in the flow rate of arsine (AsH₃). Particularly, when the flow rate of arsine (AsH₃) is set at not less than 6.4 cm³/min, the concentration of arsenic (As) in the epitaxially grown silicon layer can be brought to 10¹⁹/cm³ or so.

Therefore, by carrying out the epitaxial growth at the atmospheric pressure as in the film forming method according to the embodiment of the present invention, the concentration of arsenic (As) in the epitaxially grown silicon layer can be brought to 10¹⁹/cm³ or so without lowering the epitaxial growth rate, which has been difficult to realize by the epitaxial growth in vacuum (at a reduced pressure).

The film forming method as above-described includes the step of supplying a gas containing arsenic as a dopant into the atmosphere for epitaxial growth while keeping the epitaxial growth atmosphere at the atmospheric pressure, whereby an epitaxially grown silicon layer 22 doped with arsenic in a high concentration, for example, a concentration of not less than 1×10¹⁹/cm³ can be advantageously formed at a growth rate higher than the growth rate at the time of epitaxial growth for doping with arsenic in a low concentration in a vacuum (at a reduced pressure) according to the related art. In brief, the epitaxially grown silicon layer 22 doped with arsenic in a high concentration can be formed at a high rate.

In addition, with hydrogen chloride (HCl) introduced into the growth atmosphere in an appropriate quantity, the arsenic-containing epitaxially grown silicon layer 22 can be selectively grown only on the silicon layer present as an under layer. Moreover, there is the merit that the loading effect is not generated in this instance.

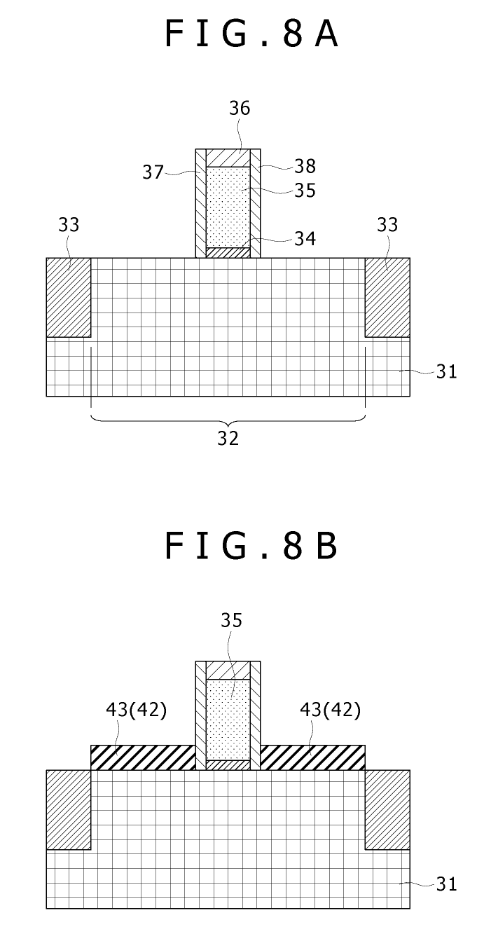

Now, a first embodiment of the method of manufacturing a semiconductor device in the present invention will be described below referring to FIGS. 8A and 8B, which are manufacturing step sectional diagrams. FIGS. 8A and 8B illustrate an example in which the film forming method in the embodiment of the present invention is applied to part of a method of manufacturing an NMOS transistor having the so-called elevated source drain structure.

As shown in FIG. 8A, device isolating regions 33 for isolating each device forming region (transistor forming region) 32 are formed by, for example, a silicon oxide based insulating film in a semiconductor substrate (silicon substrate) 31. A gate electrode 35 is formed on the upper side of the semiconductor substrate 31 in the device forming region 32, with a gate insulation film 34 therebetween. A cap insulation film 36 is formed on the gate insulation film 35, and side walls 37 and 38 are formed on side walls of the gate electrode 35. In view of the formation, in a later step, of an epitaxially grown silicon layer doped with arsenic in a high concentration on source/drain regions by epitaxial growth, the cap insulation film 36 and the side walls 37 and 38 are formed of a material which can serve as a mask at the time of the epitaxial growth, for example, silicon oxide (SiO₂), silicon nitride (SiN), silicon oxynitride (SiON) or the like.

Next, as shown in FIG. 8B, by the above-described film forming method in the embodiment of the present invention, an epitaxially grown silicon layer 42 doped with arsenic in a high concentration is selectively formed on the semiconductor substrate 31 in the source/drain forming regions on both sides of the gate electrode 35, to form elevated source drain 43, 44.

Specifically, in the case where a normal-pressure vapor phase epitaxy apparatus (not shown) is used and the inside volume of the chamber 11 is 5 to 20 L, for example, the pressure of the atmosphere for epitaxial growth is set at the atmospheric pressure (the atmospheric pressure here refers to the normal atmospheric pressure on the earth, for example, 1 atm=1013 hPa); the growth temperature (e.g., the substrate temperature) is 650 ro 700° C.; and, for example, dichlorosilane (SiH₂Cl₂) is used as a raw material gas for silicon, arsine (AsH₃) (diluted with hydrogen (H₂) to 1 vol. %, for example) is used as a raw material gas for the dopant (arsenic), hydrogen chloride (HCl) is used for effecting selective growth, and hydrogen (H₂) is used as a gas for uniformly distributing the dopant. As for the flow rates of these gases, dichlorosilane (SiH₂Cl₂) is supplied at a flow rate of 50 to 500 cm³/min, arsine (AsH₃) (diluted with hydrogen (H₂) to 1 vol. %) at 5 to 200 cm³/min, hydrogen chloride (HCl) at 15 to 200 cm³/min, and hydrogen (H₂) at 10 to 30 L/min. With the epitaxial growth conducted under these conditions, selective epitaxial growth on the source/drain regions can be achieved.

Incidentally, the ranges of the epitaxial growth conditions are adopted on the same grounds as described in the film forming method above.

Namely, the growth temperature (e.g., the substrate temperature) is set in the range of 650 to 750° C., since the epitaxial growth rate is substantially zero when the growth temperature is below 650° C., and the selective epitaxial growth is not achieved when the growth temperature is above 750° C.

In addition, the flow rate of dichlorosilane (SiH₂Cl₂) is set in the range of 50 to 500 cm³/min, since the epitaxial growth rate is substantially zero when the flow rate is less than 50 cm³/min, and the selective epitaxial growth is not achieved when the flow rate is more than 500 cm³/min.

Besides, the flow rate of arsine (AsH₃) (diluted with hydrogen (H₂) to 1 vol. %) is set in the range of 5 to 200 cm³/min, since the concentration of arsenic is insufficient and the growth rate is lower than 2 nm/min when the flow rate is below 5 cm³/min, whereas when the flow rate is above 200 cm³/min, the morphology of epitaxial growth is worsened, though a sufficient growth rate can be secured.

The flow rate of hydrogen chloride (HCl) is set in the range of 15 to 200 cm³/min, since the selective epitaxial growth is not achieved when the flow rate is less than 15 cm³/min, and the epitaxial growth does not proceed but etching occurs when the flow rate is above 200 cm³/min.

The flow rate of hydrogen (H₂) is set in the range of 10 to 30 L/min, since uniformity of the distribution of arsenic is worsened when the flow rate is less than 10 L/min, and the uniformity of the distribution of arsenic is worsened also when the flow rate is in excess of 30 L/min.

Furthermore, in the above embodiment, as the raw material gas for silicon, other gases than dichlorosilane can also be used, for example, monosilane (SiH₄), disilane (Si₂H₆), trisilane (Si₃H₈), trichlorosilane (SiHCl₃), or the like.

Besides, in the case where the inside volume of the chamber is greater than 5 to 20 L, for example, the flow rates of the gases introduced into the chamber may be regulated according to the increase in the inside volume of the chamber in such a manner that the volumetric ratio among the gas flow rates calculated from the gas flow rates will be constant and, hence, the mixing ratio of the gases inside the chamber will be kept constant, whereby the intended film can be formed regardlessly of the difference in the inside volume of the chamber.

In the method of manufacturing a semiconductor device as above, the epitaxially grown silicon layer 42 doped with arsenic in a high concentration is grown selectively on the source/drain regions by the film forming method in the present invention, whereby the elevated source drain 43, 44 can be formed. Therefore, the elevated source drain structure can be easily formed by the manufacturing method. By the doping with arsenic in a high concentration, it is possible to reduce the electric resistance of the elevated source drain 43, 44. Besides, in forming the elevated source drain 43, 44, the epitaxial silicon layer 42 can selectively be epitaxially grown in the arsenic-doped state, so that the heating step conventionally conducted after doping the elevated source drain 43, 44 with arsenic can be omitted. Therefore, it is possible to restrain the diffusion of impurities with which the other regions have been doped. Specifically, the diffusion of the impurities is restrained, whereby it is possible to reduce the diffusion depth Xj of the diffusion layer(s) formed in the semiconductor substrate (silicon substrate), so that the short channel effect upon miniaturization can be restrained. Accordingly, the performance of the transistor can be enhanced.

It should be understood by those skilled in the art that various modifications, combinations, sub-combinations and alterations may occur depending on design requirements and other factors insofar as they are within the scope of the appended claims or the equivalents thereof.

What is claimed is:

1. A film forming method for forming an arsenic-doped silicon layer by epitaxial growth, comprising the step of
supplying a gas containing arsenic as a dopant into the atmosphere for said epitaxial growth while keeping said epitaxial growth atmosphere at the atmospheric pressure.

2. The film forming method as set forth in claim 1, wherein
a hydrogen chloride gas is introduced into said epitaxial growth atmosphere.

3. A method of manufacturing a semiconductor device, comprising the step of
forming an arsenic-doped silicon layer on source/drain regions formed in a silicon substrate by selective epitaxial growth, wherein
said step of forming said arsenic-doped silicon layer
includes the step of supplying a gas containing arsenic as a dopant into the atmosphere for said selective epitaxial growth while keeping said selective epitaxial growth atmosphere at the atmospheric pressure.
